(19) United States
(12) Patent Application Publication
(10) Pub. No.: US 2022/0157632 A1
(43) Pub. Date: May 19, 2022

(54) AIRLOCK AND WAFER MACHINE

(71) Applicant: CHANGXIN MEMORY TECHNOLOGIES, INC., Hefei City (CN)

(72) Inventors: Zhengzheng Wang, Hefei (CN); Kai Liu, Hefei (CN)

(21) Appl. No.: 17/509,138

(22) Filed: Oct. 25, 2021

Related U.S. Application Data
(63) Continuation of application No. PCT/CN2021/109065, filed on Jul. 28, 2021.

(30) Foreign Application Priority Data
Nov. 18, 2020 (CN) 202011294173.0

(51) Int. Cl. H01L 21/68; H01L 21/687

(52) U.S. Cl. CPC H01L 21/68; H01L 21/6875

(57) ABSTRACT

The airlock is provided with supporting legs configured to carry a wafer. The airlock further includes a wafer position correction system. The wafer position correction system includes sensing units, adjustment units and a control system. Each sensing unit is arranged on a respective one of the supporting legs and configured to sense a pressure signal applied on said sensing unit by the wafer. The sensing units are arranged at an edge of a calibration region. The adjustment units are arranged in the airlock around a periphery of the calibration region and configured to adjustably push the wafer. The control system is electrically connected to each of the sensing units and each of the adjustment units, and configured to select and control some of the adjustment units to adjust a position of the wafer according to the pressure signal.

### CROSS-REFERENCE TO RELATED APPLICATIONS

This is a continuation application of International Patent Application No. PCT/CN2021/109065, filed on Jul. 28, 2021, which claims priority to Chinese Patent Application No. 202011294173.0, filed on Nov. 18, 2020 and entitled “AIRLOCK AND WAFER MACHINE”. The disclosures of International Patent Application No. PCT/CN2021/109065 and Chinese Patent Application No. 202011294173.0 are incorporated by reference herein in their entireties.

### TECHNICAL FIELD

The disclosure relates to the technical field of semiconductor manufacturing, in particular to an airlock and a wafer machine.

### BACKGROUND

In the wafer machine, an airlock is a component used to switch between vacuum and atmosphere. Due to poor discharge of an electrostatic chuck in a cavity of the airlock and easy abrasion of a rubber ring on a mechanical arm, a position of a wafer is prone to offset when the wafer is transferred in or out, which causes the airlock is needed to be shut down to correct the position of the wafer, thereby leading to waste of reset time, reducing the yield of the wafer machine, and easily causing wafer defects.

### SUMMARY

One aspect of the embodiments of the disclosure provides an airlock. The airlock is provided with supporting legs configured to carry a wafer. The airlock further includes a wafer position correction system. The wafer position correction system includes sensing units, adjustment units and a control system. Each sensing unit is arranged on a respective one of the supporting legs and configured to sense a pressure signal applied on said sensing unit by the wafer. The sensing units are arranged at an edge of a calibration region. The adjustment units are arranged in the airlock around a periphery of the calibration region and configured to adjustably push the wafer. The control system is electrically connected to each of the sensing units and each of the adjustment units, and configured to select and control some of the adjustment units to adjust a position of the wafer according to the pressure signal, so that a center of the wafer coincides with a center of the calibration region.

Another aspect of the embodiments of the disclosure provides a wafer machine. The wafer machine includes an airlock. The airlock is provided with supporting legs configured to carry a wafer. The airlock further includes a wafer position correction system. The wafer position correction system includes sensing units, adjustment units and a control system. Each sensing unit is arranged on a respective one of the supporting legs and configured to sense a pressure signal applied on said sensing unit by the wafer. The sensing units are arranged at an edge of a calibration region. The adjustment units are arranged in the airlock around a periphery of the calibration region and configured to adjustably push the wafer. The control system is electrically connected to each of the sensing units and each of the adjustment units, and configured to select and control some of the adjustment units to adjust a position of the wafer according to the pressure signal, so that a center of the wafer coincides with a center of the calibration region

### BRIEF DESCRIPTION OF THE DRAWINGS

FIG. 1 is a schematic plan diagram showing an arrangement of an airlock according to an exemplary embodiment;

FIG. 2 is a partially schematic diagram of an airlock illustrated in FIG. 1; and

FIG. 3 is a partially sectional diagram of an airlock illustrated in FIG. 1.

### DETAILED DESCRIPTION

The exemplary embodiments will now be described more comprehensively with reference to the accompanying drawings. However, the exemplary embodiments can be implemented in various forms and should not be construed as being limited to the embodiments set forth herein. Rather, these embodiments are provided so that the disclosure will be thorough and complete, and the concepts of the exemplary embodiments will be conveyed fully to those skilled in the art. Same reference numerals in the drawings indicate the same or similar structures, and therefore their detailed description will be omitted.

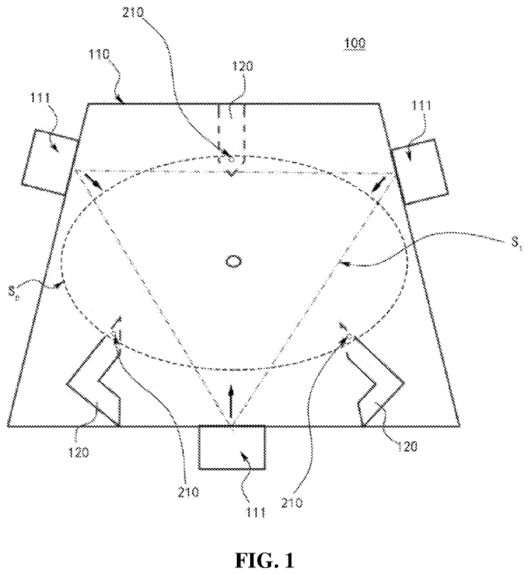

Referring to FIG. 1, a schematic plan diagram showing an arrangement of an airlock provided in the disclosure is representatively illustrated. In the exemplary embodiment, the airlock provided in the disclosure is described by taking an example of being applied to the wafer machine. It is easy for those skilled in the art to understand that in order to apply the relevant design of the disclosure to other types of equipment or other processes, various modifications, additions, substitutions, deletions or other changes are made to the following specific embodiments. These changes are still within the scope of the principle of the airlock provided in the disclosure.

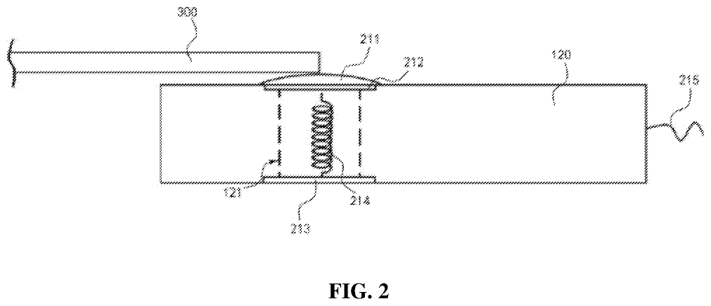

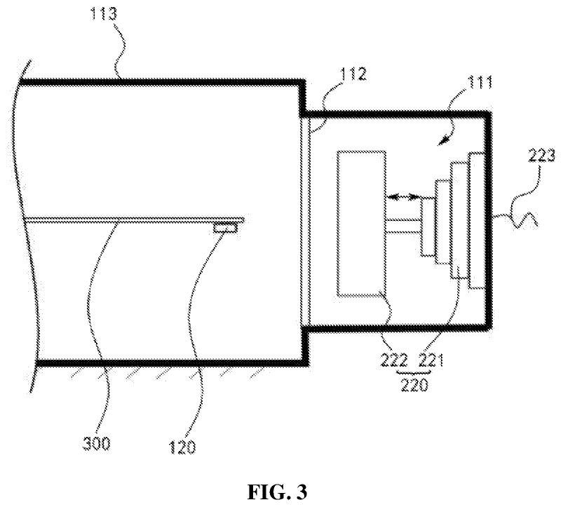

As shown in FIG. 1, in this embodiment, a plurality of supporting legs 120 are provided in the airlock 110 according to the disclosure. These supporting legs 120 are configured to carry a wafer. The airlock 110 further includes a wafer position correction system. In this embodiment, as an example, the airlock 110 is provided with three supporting legs 120. Referring to FIG. 2 and FIG. 3, FIG. 2 representatively illustrates a partially schematic diagram of the airlock 110 that can reflect the principle of the disclosure, and specifically illustrates a structure when one of the supporting legs 120 carries the wafer 300. FIG. 3 representatively illustrates a partially sectional view of the airlock 110 that can reflect the principle of the disclosure, and specifically illustrates a structure with one of the adjustment units 220 and one of the adjustment chambers 111. Structures, connection methods and functional relationships of main components of the airlock 110 provided in the disclosure will be described in detail below in combination with the above accompanying drawings.

As shown in FIG. 1 to FIG. 3, in this embodiment, the wafer position correction system includes three sensing units 210, three adjustment units 220 and a control system. Specifically, the three sensing units 210 are respectively arranged on the three supporting legs 120, and the sensing units 210 can sense the pressure signal applied on said sensing unit by the wafer 300. The three sensing units 210 are uniformly arranged at an edge of a calibration region S0. Specifically, the calibration region S0 can be understood as a standard position where the wafer 300 is carried on the supporting legs 120. In other words, when the wafer 300 is located at the standard position, the edge of the wafer 300 can just apply pressure to the three sensing units 210 at the same time, so that each sensing unit 210 can sense the pressure signal. As an example, the wafer 300 is of a circular shape. The calibration region S0 is a circular region with the same shape (the same diameter) as the wafer 300, and the three sensing units 210 are arranged on a circular path at the edge of the calibration region S0. The three sensing units 210 are uniformly spaced apart from each other on the circular path, that is, at an angle of 120 degrees apart from each other. The three adjustment units 220 are uniformly arranged in the airlock 110 around a periphery of the calibration region S0, and the adjustment units 220 can adjustably push the wafer 300. The control system is electrically connected to the each of the sensing units 210 and each of the adjustment units 220. The control system can correspondingly select and control, according to whether each sensing unit 210 senses the pressure signal, some of the adjustment units 220 to operate, so as to push the wafer 300 to adjust the position thereof, so that a center of the wafer 300 coincides with a center 0 of the calibration region S0. That is, the position correction for the wafer 300 in the calibration region S0 is realized. By means of the above-mentioned design, in the airlock 110 provided in the present disclosure, the position correction for the wafer 300 can be realized without shutting down the machine. Compared to the related art, in the disclosure, the need for shutdown and manual correction is eliminated, waste of reset time is reduced, the yield of the wafer machine is increased, and product defects such as uneven etching of the wafer 300 caused by the offset of the center position of the wafer is avoided.

Optionally, as shown in FIG. 2, in this embodiment, each sensing unit 210 may include an insulation pad 211, two conductive sheets, and an elastic member 214. Specifically, the insulation pad 211 is arranged on a top surface of each of the supporting legs 120. The two conductive sheets are vertically spaced apart from each other. For ease of description, in the present specification, the conductive sheet located above is configured as the upper conductive sheet 212, and the conductive sheet located below is configured as the lower conductive sheet 213. The upper conductive sheet 212 is arranged at a bottom portion of the insulation pad 211, and the lower conductive sheet 213 is electrically connected to the control system (for example, through a lead 215). A lower end of the elastic member 214 is connected to the lower conductive sheet 213, and an upper end of the elastic member is spaced apart from the upper conductive sheet 212. Accordingly, when there is a wafer 300 above the insulation pad 211, the insulation pad 211 is compressed by the wafer 300 to be deformed downward, and the upper conductive sheet 212 is deformable downward along with the insulation pad 211 and contact the upper end of the elastic member 214, so that the electrical connection is formed between the two conductive sheets through the elastic member 214 to form a closed circuit. The sensing units 210 sense the pressure signal responsive to that the two conductive sheets are connected with each other through the elastic member to form the closed circuit. On the contrary, if the wafer 300 is offset, and there is no wafer 300 at the corresponding position above the insulation pad 211 of each sensing unit 210, the upper conductive sheet 212 will not be deformed and will not contact the upper end of the elastic member 214, so that no electrical connection is formed between the two conductive sheets and no closed circuit is formed. The sensing units 210 do not sense the pressure signal responsive to that no electrical connection is formed between the two conductive sheets and no closed circuit is formed.

In other embodiments, the control system may also be electrically connected to the upper conductive sheet 212. That is, the control system may be electrically connected to one of the two conductive sheets. Furthermore, the elastic member 214 may be connected to the upper conductive sheet 212. In this case, the upper end of the elastic member 214 is connected to the upper conductive sheet 212, and the lower end of the elastic member is spaced apart from the lower conductive sheet 213. That is, one end of the elastic member 214 may be connected to one of the two conductive sheets, and the other end of the elastic member is spaced apart from the other one of the two conductive sheets.

Further, as shown in FIG. 2, based on the design that each sensing unit 210 includes the insulation pad 211, in this embodiment, the insulation pad 211 may be of a substantially arc-shaped structure protruding upward. In other embodiments, the insulation pad 211 may also adopt other structures, such as a cone-shaped structure protruding upward, a boss-shaped structure, etc., which is not limited to this embodiment.

Further, as shown in FIG. 2, based on the design that each sensing unit 210 includes the insulation pad 211, in this embodiment, a material of the insulation pad 211 contains rubber. In other embodiments, the material of the insulation pad 211 may also contain other insulation materials, which is not limited to this embodiment.

Further, as shown in FIG. 2, based on the design that each sensing unit 210 includes the conductive sheets, in this embodiment, a thickness h of each conductive sheet may be comprised between 1 mm and 3 mm, such as 1 mm, 1.5 mm, 2 mm, 3 mm, etc. In other embodiments, the thickness h of each conductive sheet may also be less than 1 mm, or may be greater than 3 mm, such as 0.9 mm, 3.2 mm, etc., which is not limited to this embodiment.

Further, as shown in FIG. 2, based on the design that each sensing unit 210 includes the conductive sheets, in this embodiment, each conductive sheet may be of a circular shape, and a radius R of each conductive sheet may be comprised between 1 mm and 5 mm, such as 1 mm, 2 mm, 3 mm, 4 mm, 5 mm, etc. In other embodiments, the radius R of each conductive sheet may also be less than 1 mm, or may be greater than 5 mm, such as 0.5 mm, 6 mm, etc., which is not limited to this embodiment.

Further, as shown in FIG. 2, based on the design that each sensing unit 210 includes the conductive sheets, in this embodiment, a material of the conductive sheets may be gold, silver, graphene, etc., which is not limited to this embodiment.

Further, as shown in FIG. 2, based on the design that each sensing unit 210 includes the elastic member 214, in this embodiment, the elastic member 214 may be a spring. In other embodiments, the elastic member 214 may also adopt other elastic structures, such as an elastic sheet, a leaf spring, etc., which is not limited to this embodiment.

Further, as shown in FIG. 2, based on the design that each sensing unit 210 includes the insulation pad 211, the conductive sheets, and the elastic member 214, in this embodiment, each supporting leg 120 may be provided with a mounting hole 121. The mounting hole 121 is arranged in a vertical direction and is opened onto a top surface of each supporting leg 120. The insulation pad 211 and the upper conductive sheet 212 are arranged in a top orifice of the mounting hole 121, and the lower conductive sheet 213 is arranged at a bottom portion of the mounting hole 121. The elastic member 214 is received in the mounting hole 121. In other embodiments, each sensing unit 210 may also be arranged on a respective one of the supporting legs 120 in other ways. For example, each sensing unit 210 is arranged at an edge of the respective supporting leg 120 through a bracket or a mounting seat, which is not limited to this embodiment.

Optionally, as shown in FIG. 3, in this embodiment, each adjustment unit 220 may include a retractable driving mechanism 221 and a push rod 222. Specifically, the retractable driving mechanism 221 is arranged on a side wall of the airlock 110 and is electrically connected to the control system (for example, through a lead 223). One end of the push rod 222 is connected to the retractable driving mechanism 221, and another end of the push rod extends horizontally. A material of the push rod 222 contains an insulation material, so as to ensure the insulation property in the process of pushing against the wafer 300. Accordingly, each adjustment unit 220 may drive the push rod 222 to move horizontally through the retractable driving mechanism 221.

Further, as shown in FIG. 3, based on the design that each adjustment unit 220 includes the retractable driving mechanism 221, in this embodiment, the retractable driving mechanism 221 may include a retractable sleeve. In other embodiments, the retractable driving mechanism 221 may also include other retractable structures, such as a multi-stage retractable rod, a miniature linear motor, etc., which is not limited to this embodiment.

Further, based on the design that each adjustment unit 220 includes the push rod 222, in this embodiment, a material of the push rod 222 may contain ceramic. Since the ceramic has excellent high temperature mechanical property, chemical corrosion resistance, high temperature oxidation resistance, wear resistance and good insulation property, by using ceramic as the material of the push rod 222, the insulation performance of the push rod can be ensured, while ensuring relatively stable structure and longer service life of the push rod. In other embodiments, the material of the push rod 222 may also contain other insulation materials, which is not limited to this embodiment.

Further, as shown in FIG. 3, based on the design that each adjustment unit 220 includes the retractable driving mechanism 221 and the push rod 222, in this embodiment, three adjustment chambers 111 may be provided on the side wall of the airlock 110, so that the three adjustment units 220 are respectively arranged in the three adjustment chambers 111. The number and the arrangement of the adjustment chambers 111 can be adjusted according to the number and the arrangement of the adjustment units 220. For example, each adjustment unit 220 can be independently arranged in one of the adjustment chambers 111. Based on this, for each adjustment chamber 111, a door 112 may be provided at a position on the side wall of the airlock 110 corresponding to each of the adjustment chambers 111. The door 112 may be driven by a door driving mechanism. The door driving mechanism is electrically connected to the control system. Accordingly, when the control system selects the corresponding adjustment unit 220 to operate, for example, when the retractable driving mechanism 221 drives the push rod 222 to extend, the control system simultaneously controls the corresponding door driving mechanism to drive the door 112 to open, so that the push rod 222 extends from the adjustment chamber 111 into the airlock 110. By means of the above-mentioned design, in the disclosure, it is possible to provide an independent arrangement space for each adjustment unit 220 through the adjustment chamber 111, and to ensure the airtightness of each adjustment chamber 111 through the door 112, thereby reducing the impact on an gas environment in the airlock 110, and avoiding that the adjustment unit competes with the structures such as the wafer 300 and the supporting legs 120 in the airlock 110 for the arrangement space.

Optionally, in this embodiment, the reaction time of the control system to select and control some of the adjustment units according to the pressure signal may be less than 1 s, such as 0.05 s, 0.1 s, 0.5 s, 1 s, etc. By means of the above-mentioned design, in the disclosure, it is beneficial to realize rapid position correction for the wafer 300.

Optionally, as shown in FIG. 3, in this embodiment, a cover plate 113 is provided on a top portion of the airlock 110. The cover plate 113 may be made of a transparent material. By means of the above-mentioned design, in the disclosure, real-time checking of an internal situation of the airlock 110 can be realized through the transparent cover plate 113.

It should be noted that, as shown in FIG. 1, in this embodiment, the three sensing units 210 are uniformly arranged, which is actually based on the uniform arrangement of the three supporting legs 120. In other words, each supporting leg 120 is provided with only one sensing unit 210, so that the number and the arrangement of the supporting legs 120 determine the number and the arrangement of the sensing units 210. In other embodiments, according to different correction and sensing needs, for a plurality of sensing units 210 and a plurality of supporting legs 120, only some of the supporting legs 120 may be provided with a sensing unit 210, which is not limited to this embodiment.

It should be noted that, as shown in FIG. 1, in this embodiment, as an example, the airlock 110 includes three supporting legs 120, that is, the wafer position correction system includes three sensing units 210. In other embodiments, the airlock 110 may also include different number of supporting legs 120, such as four, five, eight, etc. Based on this, the wafer position correction system may also include different number of sensing units 210, such as two, four, five, six, etc., which is not limited to this embodiment.

It should be noted that, as shown in FIG. 1, in this embodiment, as an example, the wafer position correction system includes three adjustment units 220. In other embodiments, the airlock 110 may also include different number of adjustment units 220, such as two, four, five, six, etc., which is not limited to this embodiment.

In addition, as shown in FIG. 1, in this embodiment, the lines connecting the three adjustment units 220 roughly define a triangular region, i.e., a reference region S1 shown in the figure. Since the three adjustment units 220 are uniformly arranged, the shape of the reference region S1 is approximately an equilateral triangle, and the geometric center of a corresponding shape of the reference region S1 (for example, the center of the above-mentioned equilateral triangle) coincides with the center O of the above-mentioned calibration region S0. In other embodiments, when the number of the adjustment units 220 is more than three, the corresponding shape of the above-mentioned reference region S1 defined by each adjustment unit 220 is a regular polygon, and the center of the regular polygon coincides with the center O of the calibration region S0.

It should be noted that, as shown in FIG. 1, in this embodiment, as an example, the number of the sensing units 210 is the same as the number of the adjustment units 220, for example, three. In other embodiments, the number of the sensing units 210 may also be different from the number of the adjustment units 220, which is not limited to this embodiment.

Further, as shown in FIG. 1, based on the design that the number of the sensing units 210 is the same as the number of the adjustment units 220, in this embodiment, each of the sensing units 210 and each of the adjustment units 220 may be evenly spaced apart from each other and alternately arranged with each other in a circumferential direction of the calibration region S0. Based on this, in this embodiment, taking three sensing units 210 and three adjustment units 220 as an example, when one of the three sensing units 210 does not sense a pressure signal, the control system may select the adjustment unit 220 opposite to the one of the three sensing units 210, that is, the adjustment unit 220 arranged between the other two of the three sensing units 210, to perform an adjustment operation. For another example, when two of the three sensing units 210 do not sense a pressure signal, the control system may select two adjustment units 220 opposite to the two sensing units 210 respectively, that is, the two adjustment units 220 other than the adjustment unit 220 opposite to the other one of the three sensing units 210 which can sense the pressure signal, to perform the adjustment operation. Based on the description of the calibration region S0 and the carrying range of the wafer 300 in the present specification, when the wafer 300 is carried on the supporting legs 120, it is impossible that all the sensing units 210 do not sense the pressure signal, which thus will not be repeated herein.

Overall, according to the airlock provided in the disclosure, a plurality of sensing units are respectively provided on a plurality of supporting legs, and a plurality of adjustment units are provided in the airlock. Accordingly, the sensing units are configured to sense the pressure signal applied on said sensing unit by the wafer, and the control system is configured to select and control some of the adjustment units to adjust the position of the wafer according to the pressure signal, so as to realize the position correction for the wafer. By means of the above-mentioned design, in the airlock provided in the disclosure, the position correction for the wafer can be realized without shutting down the machine. Compared to the related art, in the disclosure, the need for shutdown and manual correction is eliminated, waste of reset time is reduces, the yield of the wafer machine is increased, and product defects such as uneven etching of the wafer caused by the offset of the center position of the wafer is avoided.

Based on the above detailed description of an exemplary embodiment of the airlock provided in the disclosure, an exemplary embodiment of a wafer machine provided in the disclosure will be described below.

In this embodiment, the wafer machine provided in the disclosure includes the airlock which is provided in the disclosure and described in detail in the above-mentioned embodiments.

Overall, according to the wafer machine provided in the disclosure, by means of the airlock provided in the disclosure, the position correction for the wafer can be realized without shutting down the machine. Compared to the related art, in the disclosure, the need for shutdown and manual correction is eliminated, waste of reset time is reduced, the yield of the wafer machine is increased, and product defects such as uneven etching of the wafer caused by the offset of the center position of the wafer is avoided.

Although the disclosure has been described with reference to several exemplary embodiments, it should be understood that the terminology used herein is illustrative and exemplary, and not restrictive. Since the disclosure can be implemented in various forms without departing from the spirit or essence of the disclosure, it should be understood that the above embodiments are not limited to any of the foregoing details, but should be broadly interpreted within the spirit and scope defined by the appended claims. Therefore, all changes and modifications falling within the scope of the claims or their equivalents shall be included by the appended claims.

1. An airlock, the airlock being provided with supporting legs configured to carry a wafer, the airlock further comprising a wafer position correction system, the wafer position correction system comprising:
sensing components, each sensing component being arranged on a respective one of the supporting legs and configured to sense a pressure signal applied on said sensing component by the wafer, the sensing components being arranged at an edge of a calibration region;
adjustment components arranged in the airlock around a periphery of the calibration region and configured to adjustably push the wafer; and
a control system electrically connected to each of the sensing components and each of the adjustment components, and configured to select and control some of the adjustment components to adjust a position of the wafer according to the pressure signal, so that a center of the wafer coincides with a center of the calibration region.

2. The airlock of claim 1, wherein each of the sensing components comprises:
an insulation pad arranged on a top surface of each of the supporting legs;
two conductive sheets, which are an upper conductive sheet and a lower conductive sheet, the upper conductive sheet being arranged at a bottom portion of the insulation pad, the lower conductive sheet being arranged below the upper conductive sheet, and one of the two conductive sheets being electrically connected to the control system; and
an elastic member, one end of the elastic member being connected to one of the two conductive sheets, and another end of the elastic member being spaced apart from the other one of the two conductive sheets,
wherein the upper conductive sheet is deformable downward along with the insulation pad when the insulation pad is compressed, so that the two conductive sheets are connected with each other through the elastic member to form a closed circuit, and wherein the sensing components sense the pressure signal responsive to that the two conductive sheets are connected with each other through the elastic member to form the closed circuit.

3. The airlock of claim 2, wherein the insulation pad is of an arc-shaped structure protruding upward.

4. The airlock of claim 2, wherein a material of the insulation pad comprises rubber.

5. The airlock of claim 2, wherein a thickness of each conductive sheet is comprised between 1 mm and 3 mm.

6. The airlock of claim 2, wherein a radius of each conductive sheet is comprised between 1 mm and 5 mm.

7. The airlock of claim 1, wherein each of the adjustment components comprises:
a retractable driving mechanism arranged on a side wall of the airlock and electrically connected to the control system; and
a push rod, one end of the push rod being connected to the retractable driving mechanism, another end of the push rod horizontally extending, and a material of the push rod comprising an insulation material,
wherein each of the adjustment components drives the push rod to horizontally move through the retractable driving mechanism.

8. The airlock of claim 7, wherein adjustment chambers are provided on the side wall of the airlock, each of the adjustment components is arranged in a respective one of the adjustment chambers, a door is provided at a position on the side wall of the airlock corresponding to each of the adjustment chambers and is driven by a door driving mechanism, and the door driving mechanism is electrically connected to the control system.

9. The airlock of claim 1, wherein a cover plate is provided on a top portion of the airlock, and the cover plate is made of a transparent material.

10. The airlock of claim 1, wherein the wafer position correction system comprises at least three sensing components.

11. The airlock of claim 2, wherein the wafer position correction system comprises at least three sensing components.

12. The airlock of claim 3, wherein the wafer position correction system comprises at least three sensing components.

13. The airlock of claim 4, wherein the wafer position correction system comprises at least three sensing components.

14. The airlock of claim 5, wherein the wafer position correction system comprises at least three sensing components.

15. The airlock of claim 6, wherein the wafer position correction system comprises at least three sensing components.

16. The airlock of claim 7, wherein the wafer position correction system comprises at least three sensing components.

17. The airlock of claim 1, wherein the wafer position correction system comprises at least three adjustment components.

18. The airlock of claim 1, wherein the number of the sensing components is the same as the number of the adjustment components.

19. The airlock of claim 18, wherein the wafer position correction system comprises at least two sensing components and at least two adjustment components, and each of the sensing components and each of the adjustment components are evenly spaced apart from each other and alternately arranged with each other in a circumferential direction of the calibration region.

20. A wafer machine, comprising an airlock, wherein the airlock is provided with supporting legs configured to carry a wafer, the airlock further comprises a wafer position correction system, the wafer position correction system comprises:
sensing components, each sensing component being arranged on a respective one of the supporting legs and configured to sense a pressure signal applied on said sensing component by the wafer, the sensing components being arranged at an edge of a calibration region;
adjustment components arranged in the airlock around a periphery of the calibration region and configured to adjustably push the wafer; and
a control system electrically connected to each of the sensing components and each of the adjustment components, and configured to select and control some of the adjustment components to adjust a position of the wafer according to the pressure signal, so that a center of the wafer coincides with a center of the calibration region.
